(19) United States
(12) Patent Application Publication
(10) Pub. No.: US 2022/0165972 A1
(43) Pub. Date: May 26, 2022

(54) FLEXIBLE STRUCTURE PHOTODETECTOR

(71) Applicant: CHUNG ANG UNIVERSITY INDUSTRY ACADEMIC COOPERATION FOUNDATION, SEOUL (KR)

(72) Inventors: Dong Hwan Wang, Seoul (KR); Woongsik Jang, Seoul (KR)

(21) Appl. No.: 17/502,006

(22) Filed: Oct. 14, 2021

(30) Foreign Application Priority Data
Oct. 16, 2020 (KR) 10-2020-0134644

(51) Int. Cl. H01L 51/44; H01L 27/30; H01L 51/00; H01L 51/42

(52) U.S. Cl. CPC H01L 51/444; H01L 51/4273; H01L 51/0097; H01L 27/307

(57) ABSTRACT

A photodetector according to an embodiment of the present disclosure includes: a carbon allotrope electrode, wherein the carbon allotrope electrode has an average transmittance in a range from 85% to 95% at a wavelength in a range from 380 nm to 780 nm.

### CROSS-REFERENCE TO RELATED APPLICATION

This application claims priority under 35 U.S.C. § 119 to Korean Patent Application No. 10-2020-0134644, filed on Oct. 16, 2020, in the Korean Intellectual Property Office (KIPO), the disclosure of which is incorporated by reference herein in its entirety.

### TECHNICAL FIELD

Embodiments of the present disclosure relate to a photodetector capable of realizing curved surfaces and flexibility by introducing a carbon allotrope electrode capable of suppressing dark current.

### BACKGROUND ART

Photodetectors are semiconductor devices that detect light energy to convert it into an electrical signal and have a concept that includes all semiconductor-based sensors such image sensors, chemical detection sensors, and medical sensors.

An organic photodetector has excellent color separation (e.g., resolving) ability due to a photoreaction layer composition including an organic material. In particular, it may realize curved surfaces and a flexible structure of an organic photoreactive layer, and accordingly, advantages may be achieved in that loss of incident light may be substantially minimized and lens design may be simplified.

However, previous studies reported on photodetectors have been focused on development of photoreactive layer materials, and despite the excellent flexibility of the organic photoreactive layer, research and development are carried out limited to electrodes based on inorganic materials such as oxides that lack flexibility.

Conventionally used oxide electrodes have low flexibility, which makes it difficult to make a curved and flexible device, and an injection barrier is lowered due to a high work function, thereby degrading performance by increasing a dark current.

### Prior Art Literature

Japanese Laid-Open Patent JP 2007-035893 A

### SUMMARY

Embodiments of the present disclosure may be directed to successfully implementing curved surfaces and flexibility of photodetectors that are stable to mechanical deformation such as bending and have excellent bending strain.

Embodiments of the present disclosure may also be directed to a photodetector improved in terms of photodetection ability by suppressing dark current, as compared to conventional oxide electrode and conductive polymer electrode materials.

According to an embodiment, a photodetector includes: a carbon allotrope electrode, wherein the carbon allotrope electrode has an average transmittance in a range from 85% to 95% at a wavelength in a range from 380 nm to 780 nm.

In some embodiments, the photodetector may have a flexible structure.

In some embodiments, the carbon allotrope electrode may have a trap density adjusted to a range from 1.00×10¹⁰ cm⁻³ to 1.00×10¹⁷ cm⁻³.

In some embodiments, the carbon allotrope electrode may have a work function adjusted to a range from 4.80 eV to 5.60 eV.

In some embodiments, the carbon allotrope electrode may be p-doped with nitric acid.

In some embodiments, the carbon allotrope electrode may be deposited on a polyethylene naphthalate (PEN) substrate.

In some embodiments, the photodetector may further include, as a photoreactive layer, a fullerene derivative and PBDTTT-EFT (poly [4,8-bis(5-(2-ethylhexyl)thiophen-2-yl)benzo[1,2-b ;4,5-b′]dithiophene-2,6-diyl-alt-(4-(2-ethylhexyl)-3-fluorothieno[3,4-b]thiophene-)-2-carboxylate-2-6-diyl)]).

In some embodiments, the photodetector may further include, as an electron blocking layer, PEDOT:PSS (poly(3,4-ethylenediocy-thiophene) doped with poly(styrenesulfonic acid)).

In some embodiments, the photodetector may further include polyethyleneimine (PEI) as a hole blocking layer.

In some embodiments, a LUMO energy of a photoreactive layer acceptor formed on the carbon allotrope electrode is adjusted to a range from 4.40 eV to 4.80 eV.

In some embodiments, a method of preparing the photodetector includes: preparing a carbon allotrope film by chemical vapor deposition (CVD); depositing the carbon allotrope film on a substrate and then p-doping the carbon allotrope film with nitric acid; applying a bulk heterojunction (BHJ) solution as a photoreactive layer composition on the p-doped film; applying a charge blocking layer composition on the film applied with the photoreactive layer composition; and depositing a negative electrode on the film applied with the charge blocking layer composition.

### Technical Means

According to an embodiment, a non-conductive adhesive film for semiconductor packages includes: a base; and an adhesive layer disposed on one surface of the base and having a tensile modulus in a range of 2 to 4 GPa at 25° C.

In some embodiments, the adhesive layer may have a weight reduction rate of 1% or less at 250° C. by thermogravimetric analysis (TGA).

In some embodiments, the adhesive layer may have an onset temperature in a range of 160 to 200° C.

According to an embodiment, a method of manufacturing a semiconductor package includes: (S100) sequentially and alternately laminating, on a substrate, the adhesive layer of the non-conductive adhesive film of any one of claims 1 to 7, and a semiconductor device having a through silicon via (TSV) structure on at least one surface of which a connection terminal is disposed to form a multi layered laminate; (S200) bonding connection terminals of respective semiconductor devices in the laminate to each other by thermo-compressing the laminate; and (S300) curing the adhesive layer in the thermo-compressed laminate.

### Effects of the Invention

According to one or more embodiments of the present disclosure, it is possible to improve reliability of a semiconductor package by substantially minimizing warpage deformation and slip properties during packaging of the semiconductor device.

### BRIEF DESCRIPTION OF THE DRAWINGS

A more complete appreciation of the present disclosure will become more apparent by describing in detail embodiments thereof with reference to the accompanying drawings, wherein:

FIG. 1 is a schematic diagram and an actual photograph illustrating a photodetector implemented according to an embodiment of the present disclosure;

FIGS. 2(a) and 2(b) are graphs illustrating (a) a transmittance and (b) a sheet resistance according to a transmittance of a carbon allotrope according to an embodiment of the present disclosure;

FIGS. 2(c) and 2(d) are graphs illustrating (c) a dark current and (d) a photodetection ability of an organic photodetector to which a carbon allotrope electrode according to an embodiment of the present disclosure is applied;

FIGS. 3(a) to 3(d) illustrate (a) a dark current, (b) a photodetection ability, (c) a linear dynamic region, and (d) trap density characteristics of organic photodetectors according to an embodiment of the present disclosure and a comparative example;

FIG. 4 is a schematic diagram illustrating a charge injection mechanism of photodetectors according to an embodiment of the present disclosure and a comparative example;

FIG. 5(a) is a graph illustrating a work function of electrodes according to an embodiment of the present disclosure and a comparative example;

FIGS. 5(b) to 5(d) are graphs illustrating an energy level analysis of a photoreactive layer of photodetectors according to an embodiment of the present disclosure and a comparative example; and

FIGS. 6(a) and 6(b) are graphs illustrating stability of photodetectors according to an embodiment of the present disclosure and a comparative example against mechanical stress.

### DETAILED DESCRIPTION

The following embodiments are only for illustrating the present disclosure and should not be construed as limiting the scope of the present disclosure by these examples.

As used herein, terms such as “including” and “comprising” should be understood as open-ended terms, including the possibility of including other embodiments.

The recitation of one or more preferred embodiments herein does not imply that other embodiments are not useful and is not intended to exclude other embodiments from the scope of the invention.

As used herein, when a member is said to be positioned “on” or “above” another member, this includes not only a case in which a member is in contact with another member but also a case in which another member exists between the two members.

As used herein, a photodetector according to an embodiment of the present disclosure includes a carbon allotrope electrode.

Here, the carbon allotrope electrode means an electrode including a carbon allotrope, consisting essentially of a carbon allotrope, or consisting of a carbon allotrope. The carbon allotrope may be graphene, graphite, fullerene, carbon nanotubes, carbon nanofibers, or carbon fibers, and combinations thereof, and more preferably carbon nanotubes.

The photodetector according to an embodiment of the present disclosure introduces, to the electrode, a carbon allotrope material adjusted to suppress flow of charges in a reverse direction, and accordingly, it is possible to manufacture a photodetector in which curved surfaces and flexibility are actually realized.

In addition, the present disclosure discloses an electron injection mechanism through a photoelectron yield spectroscopy (PYS) analysis, and accordingly, a photodetector proven to exhibit characteristics of suppressing dark current and improved photodetection ability may be manufactured by controlling a work function and a LUMO energy of a photoreactive layer acceptor.

According to an embodiment of the present disclosure, in order to manufacture a photodetector with substantially optimal performance, a packing density of a carbon allotrope electrode is adjusted to control a transmittance and a sheet resistance of the carbon allotrope electrode. When the packing density of the carbon allotrope electrode is high, a short circuit may occur in a network, and on the other hand, when the packing density is low, a high trap density is exhibited due to a flat shape.

In addition, according to an embodiment of the present disclosure, a high electron injection barrier is induced by controlling a work function.

The carbon allotrope electrode according to an embodiment of the present disclosure has an average transmittance adjusted to a range from 85 to 95%, more preferably 87 to 93%, and more preferably 89 to 91% at a wavelength in a range from 380 to 780 nm. When the average transmittance exceeds the above numerical range, a short circuit may occur in the network, and if it is less than the above numerical range, it may cause a high trap density due to a flat shape. In addition, it is possible to implement a photodetector having a flexible structure with improved mechanical stability within the above range.

A trap density of the carbon allotrope electrode may be adjusted to a range from 1.00×10¹⁰ to 1.00×10¹⁷ cm⁻³, 1.00×10¹⁰ to 1.65×10¹⁵ cm⁻³, and more particularly, 1.00×10¹⁰ to 1.60×10¹⁵ cm⁻³. By adjusting the trap density to the above numerical range, it is possible to implement a photodetector having a flexible structure with improved mechanical stability. In addition, by adjusting the trap density to the above numerical range, the carbon allotrope electrode may have a low dark current value of the pico-ampere level or less.

In an embodiment, the photodetector may have a flexible structure.

In an embodiment of the present disclosure, by introducing, to the electrode, a carbon allotrope material capable of suppressing charge flow in a reverse direction, and by adjusting a trap density and an average transmittance, at a wavelength in a range from 380 to 780 nm, of a carbon allotrope material of the electrode, a photodetector having a flexible structure may be implemented.

Dissimilar to a conventional electrode to which other oxides or conductive polymer materials are applied as an electrode, by applying the carbon allotrope electrode adjusted in the above-described manner in an embodiment of the present disclosure, flexibility may be further increased.

The carbon allotrope electrode may have a work function adjusted to a range from 4.80 to 5.60 eV, from 5.00 to 5.60 eV, from 5.20 to 5.60 eV, from 5.30 to 5.60 eV, or from 5.40 to 5.60 eV.

In the photodetector, a LUMO energy of a photoreactive layer acceptor formed on the carbon allotrope electrode may be adjusted to a range from 4.40 to 4.80 eV by a photoelectron yield spectroscopy (PYS) analysis. Interestingly, it was confirmed that the LUMO energy of the photoreactive layer acceptor depends on a work function of a bottom electrode.

Values of the work function of the electrode and the LUMO energy of the photoreactive layer acceptor may be determined by spin-coating a solution in which the photoreactive layer acceptor and a donor are mixed to form a film on the electrode, and then calculating the values through a photoelectron yield spectroscopy (PYS) analysis.

The present inventors were able to determine an energy level of elements in a bulk heterojunction (BHJ) film of each electrode by considering energy level banding which predicts a direct tunneling mechanism. In addition, by controlling the work function and the LUMO energy of the photoreactive layer acceptor based on results of the above-described analysis, it is possible to realize a photodetector having a flexible structure with improved mechanical stability, while having low dark current and improved photodetection ability.

In an embodiment, the carbon allotrope electrode may be p-doped with nitric acid. By the doping process, an effect of reducing a sheet resistance may be achieved.

In an embodiment of the present disclosure, a photodetector having a flexible structure may be implemented by introducing carbon allotrope materials as an electrode of a flexible substrate. As an example, the substrate may be a polymer substrate such as polycarbonate, polyimide, polyethylene terephthalate, or polyethylene naphthalate. In addition, as a preferred embodiment, the carbon allotrope electrode may be deposited on a polyethylene naphthalate (PEN) substrate. However, if a photodetector having a flexible structure may be implemented, the present disclosure is not particularly limited thereto.

As a more preferred embodiment, the photodetector may include a fullerene derivative and PBDTTT-EFT (poly[4,8-bis(5-(2-ethylhexyl)thiophen-2-yl)benzo[1,2-b;4,5-b′]dithiophene-2,6-diyl-alt-(4-(2-ethylhexyl)-3-fluorothieno[3,4-b]thiophene-)-2-carboxylate-2-6-diyl)]) which interact with the carbon allotrope electrode and has excellent photosensitivity in an entire visible spectrum. However, as long as it may be used as a photoreactive layer of the photodetector, the present disclosure is not particularly limited thereto.

In addition, the photosensitive layer composition for the photodetector may further include one or more additives of 1,8-diiodooctane (DIO), 1-chloronaphthalene (1-CN), diphenylether (DPE), octane dithiol, and tetrabromothiophene, but the present disclosure is not particularly limited thereto.

In a more preferred embodiment, the photodetector may further include PEDOT:PSS (poly(3,4-ethylenediocy-thiophene) doped with poly(styrenesulfonic acid)) which may interact with the carbon allotrope electrode to prevent direct contact between the electrode and the photoreactive layer and suppress a leakage path which may increase dark current. However, as long as it may be used as an electron blocking layer of the photodetector, the present disclosure is not particularly limited thereto.

In a more preferred embodiment, the photodetector may further include polyethyleneimine (PEI) which may interact with the carbon allotrope electrode to prevent direct contact between the electrode and the photoreactive layer and suppress a leakage path which may increase dark current. However, as long as it may be used as a hole blocking layer of the photodetector, the present disclosure is not particularly limited thereto.

The photodetector may further include a second electrode opposite to the carbon allotrope electrode, and the second electrode may include gold (Au), silver (Ag), platinum (Pt), palladium (Pd), copper (Cu), aluminum (Al), carbon (C), cobalt sulfide (CoS), copper sulfide (CuS), nickel oxide (NiO), or a mixture thereof, but the present disclosure is not particularly limited thereto.

The photodetector according to an embodiment of the present disclosure may maintain mechanical stability even after 500 bending tests at a bending radius of 7.5 nm and a bending strain of 0.8 %.

A method of manufacturing a photodetector according to an embodiment of the present disclosure includes: preparing a carbon allotrope film by chemical vapor deposition (CVD); depositing the carbon allotrope film on a substrate, and then p-doping the carbon allotrope film with nitric acid; applying a bulk heterojunction (BHJ) solution as a photoreactive layer composition on the p-doped film; applying a charge blocking layer composition on the film applied with the photoreactive layer composition; and depositing a second electrode on the film applied with the charge blocking layer composition.

The photodetector manufactured by each step is as described above.

Hereinafter, the present disclosure will be described in more detail through the following embodiments.

### <Embodiment 1> Transmittance 80%

A single-walled carbon nanotube (SWNT) in which high-purity and long nanotube bundles are randomly oriented were synthesized in a reaction tube with a diameter of 150 nm by a CVD deposition. In such a case, a controlled amount of CO₂ was added together with CO so that the carbon nanotubes were to stably grow. Next, the prepared carbon nanotube film was laminated on a polyethylene naphthalate (PEN) substrate, followed by HNO3 doping. The prepared carbon nanotube had an average transmittance (AVT) of 80.40% at a wavelength in a range from 380 to 780 nm.

Next, a bulk heterojunction (BHJ) solution including PBDTTT-EFT and PC₇₁BM with a weight ratio of 1:1.5 and having a concentration of 50 mg/ml, together with 1,8-diiodooctane (3 vol. %), was added to chlorobenzene. The concentration of solution of the carbon nanotube electrode was applied for thickness of 300 nm. Next, polyethyleneimine (PEI) included at 2.0 wt. % in ethanol was applied on the BHJ film. Finally, an Al electrode was thermally deposited to a thickness of 100 nm at 3.0×10⁻⁶ Torr using a thermal evaporator.

### <Embodiment 2> Transmittance 90%

A photodetector to which a carbon nanotube electrode having an average transmittance (AVT) of 90.37% at a wavelength in a range from 380 to 780 nm was prepared in the same manner as in Embodiment 1.

### <Embodiment 3> Transmittance 95%

A photodetector to which a carbon nanotube electrode having an average transmittance (AVT) of 95.42% at a wavelength in a range from 380 to 780 nm was prepared in the same manner as in Embodiment 1.

### <Comparative Example 1> Preparation of Photodetector to which ITO Electrode is Applied

A photodetector to which an IPO electrode is applied was manufactured in the same manner as in Embodiment 1, except that indium tin oxide (ITO) was laminated on a polyethylene naphthalate (PEN) substrate.

### <Comparative Example 2> Preparation of a Photodetector to which PEDOT:PSS Electrode is Applied

A PEDOT:PSS electrode was formed on a polyethylene naphthalate (PEN) substrate by double-layer spin casting of PEDOT:PSS, methanol, and a dimethyl sulfoxide solution. After exposure to UV ozone for 20 minutes for surface modification, PEDOT:PSS was spin-coated on a polyethylene naphthalate (PEN) substrate and then annealed on a hot plate at 100° C. Other than that, a photodetector to which a PEDOT:PSS electrode was applied was manufactured in the same manner as in Embodiment 1.

[Analysis Method]

Electric performance was analyzed by measuring dark current, photocurrent and reactivity under bias in a reverse direction (reverse bias).

An association between an electron injection barrier and a dark current in the electrode was analyzed by examining the BHJ film coated on the electrode through a photoelectron yield spectroscopy (PYS) analysis.

By calculating an electron injection barrier, a work function of the carbon allotrope for realizing the substantially best-performing photodetector electrode was analyzed.

The mechanical stability of the photodetector was analyzed by calculating a bending strain through 500 bending tests.

The surface images of the CNT electrodes and PEDOT:PSS coated onto each CNT electrode were obtained by SEM (Auriga, Carl Zeiss, Germany) and AFM (NX10, Park Systems, Republic of Korea). The current-voltage measurements of the organic photodetectors (OPDs) were performed with a potentiostat (Ivium CompactStat, Ivium Technologies, Eindhoven, Netherlands). The photocurrent was measured as a function of wavelength after power calibration (LS150, ABET Technologies, Milford, Connecticut, United States) with a monochromator (MonoRa-500i, Dongwoo Optron, Gyunggi-Do, Republic of Korea). The energy levels were determined by PYS (AC-2, Riken Keiki, Japan). and UV-Vis spectrophotometry (Lambda 365, Perkin-Elmer, United States). The impedance spectroscopy of the OPDs was performed using a potentiostat (ZIVE SP1, Zivelab, Republic of Korea). All electronic measurements were conducted in a metal box (Faraday cage) for electron shielding.

The trap density (Nₜ) can be derived from its relationship with V_{TFL} as the following Equation 1:

$${V}_{T F L} = \frac{e {N}_{t} {d}^{2}}{2 {ɛ}_{r} {ɛ}_{o}} , \qquad [ Equation 1 ]$$

where e and d are the elementary charge and thickness of the photosensitive layer, respectively.

The LUMO energy of the acceptor can be derived by considering energy level bending using PYS analysis.

### Experimental Example 1

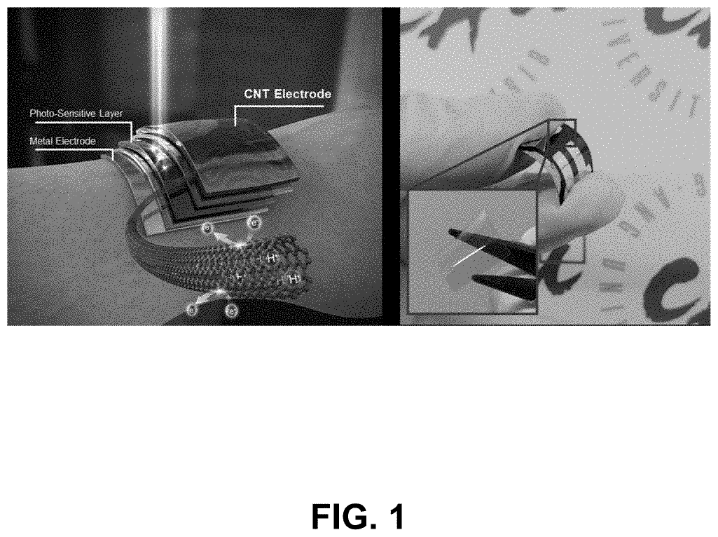

Referring to FIG. 1, it may be appreciated that a photodetector in which curved surfaces and flexibility are substantially realized were manufactured.

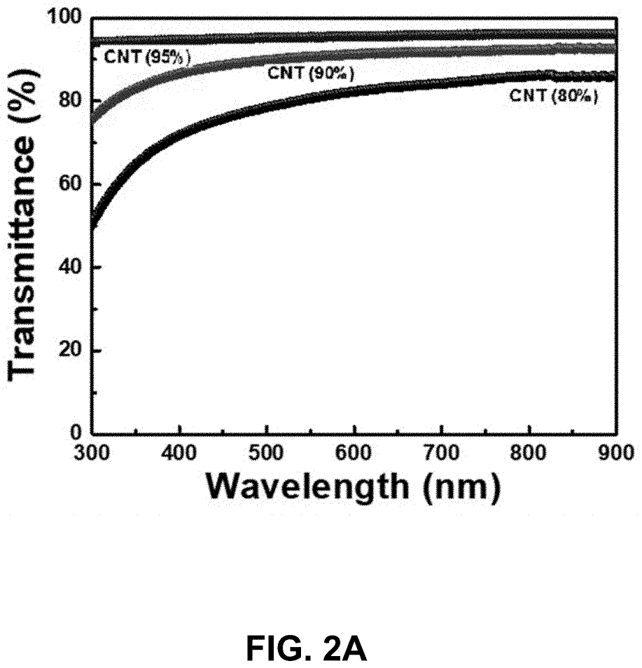

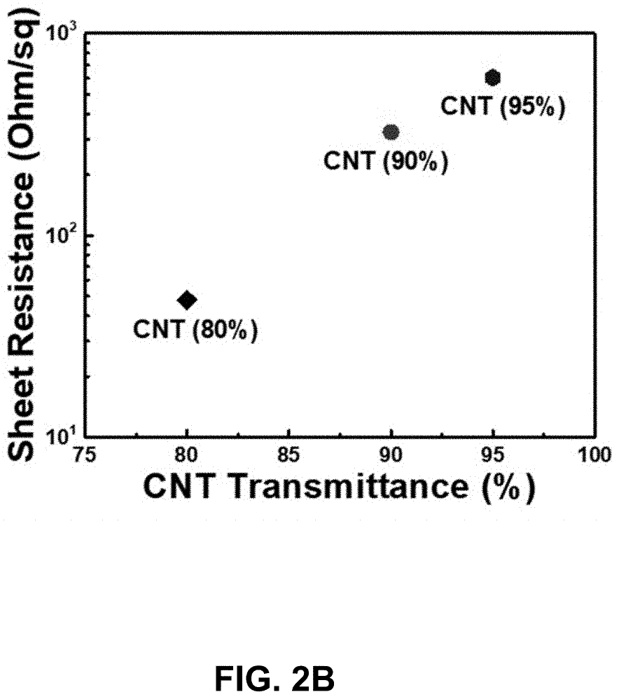

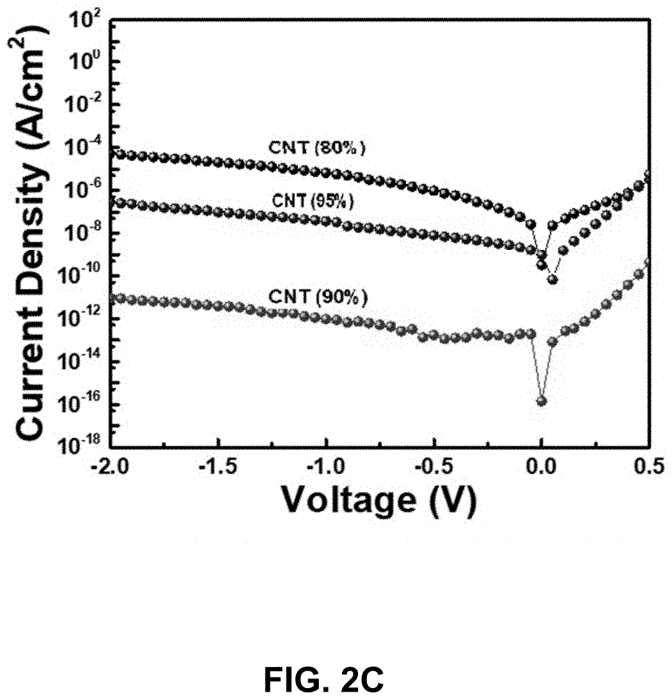

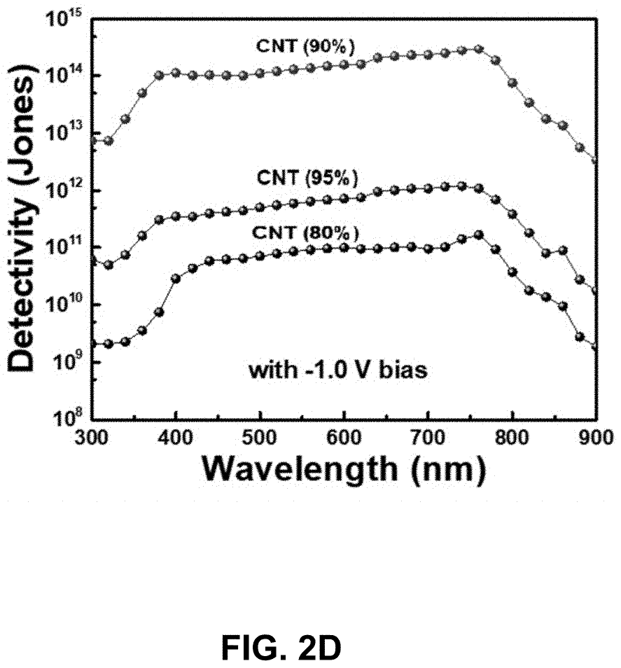

Referring to FIG. 2(a), average transmittances over a visible light range of the carbon nanotube electrodes according to Embodiments 1 to 3 were checked.

Referring to FIG. 2(b), it may be appreciated that a sheet resistance of the electrodes according to Embodiments 1 to 3 was inversely proportional to a transmittance. The sheet resistances were measured with a 4-point probe method using a source meter unit. The transmittance and sheet resistance of each electrode directly affect photocurrent and dark current of the photodetector.

FIG. 2(c) shows J-V characteristics of the photodetectors according to Embodiments 1 to 3 measured in a dark state. This shows a different trend from photocurrent, and the CNT (90%) showed extremely suppressed dark current values of the picoampere level (9.62×10⁻¹³ A/cm²) or less. Since the p-doped carbon nanotube electrode has a work function deeper than −5 eV regardless of the CNT density, a high OB for electron injection may be obtained. However, in the case of CNT (80%) and CNT (95%), they show high dark currents despite their deep work functions.

FIG. 2(d) illustrates an analysis of a detection rate (e.g., detectivity) (D*) considering a signal current to a dark current ratio by Equation 2 below.

$${D}^{*} = \frac{R}{\sqrt{( 2 {q}_{e} {J}_{d} )}} = \frac{\frac{{J}_{p h}}{{L}_{l i g h t}}}{\sqrt{( 2 q {j}_{d} )}} , \qquad [ Equation 2 ]$$

where q is the elementary charge and J_{d} is the dark current density (units of Jones are equivalent to cm Hz^{1/2} W⁻¹).

According to the above analysis, it may be appreciated that the photodetector based on CNT (90%) has the highest detection rate at −1 V bias. That is, it may be appreciated that the detection rate is improved with the trap density adjusted in the reverse bias and in the absence of a leakage path.

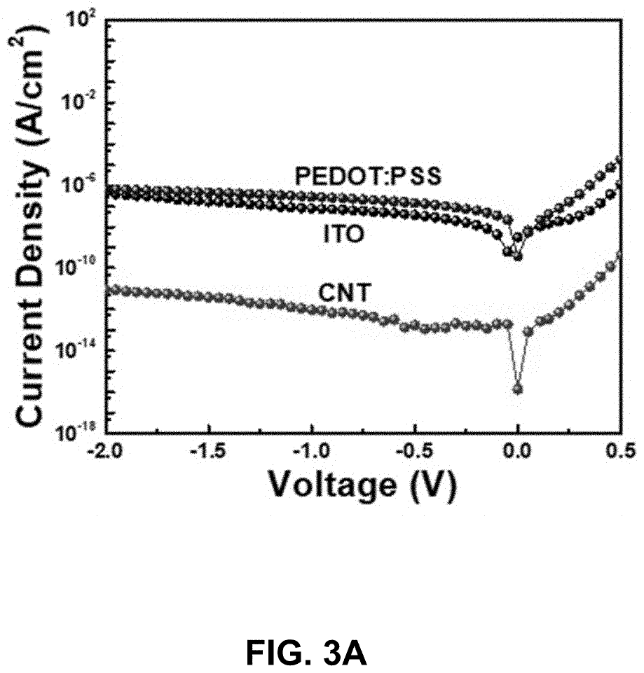

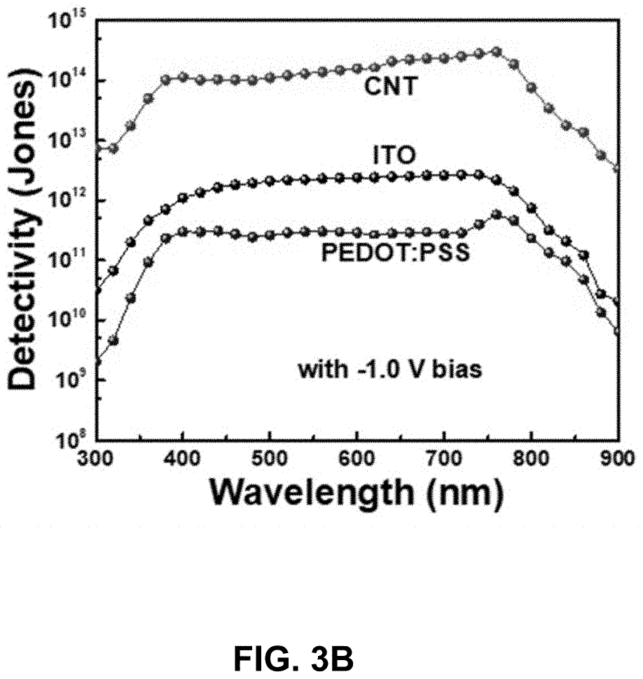

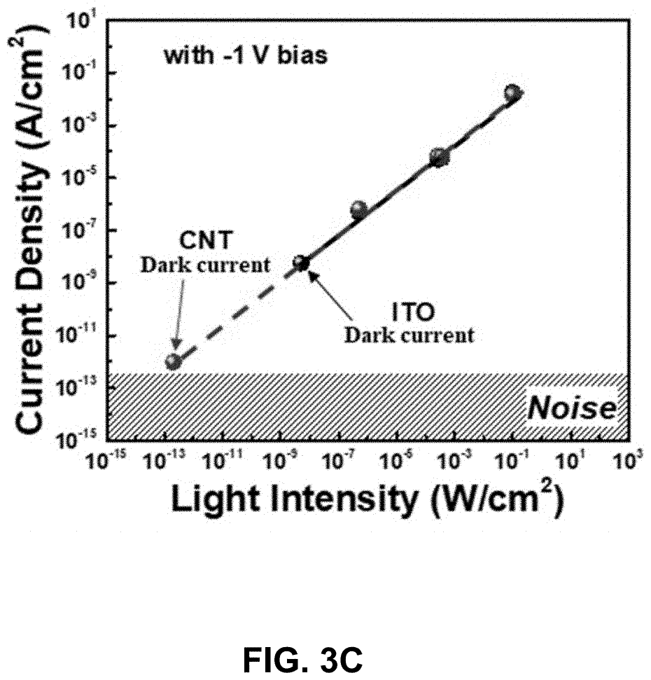

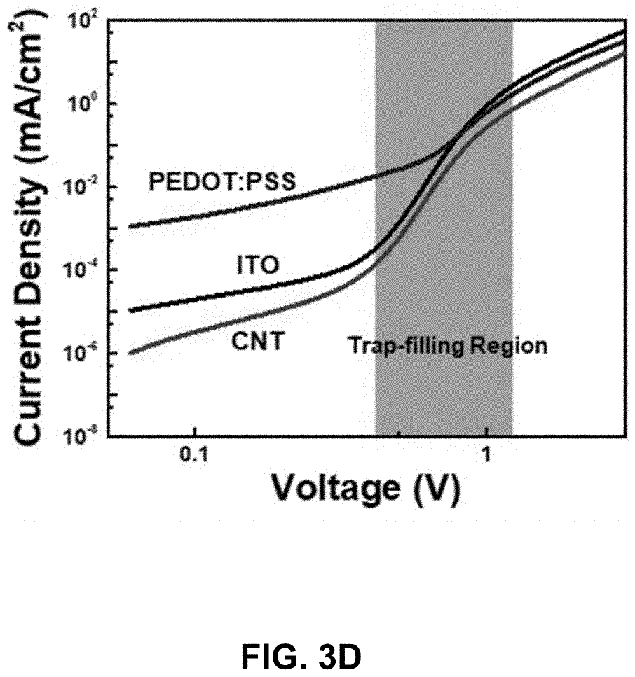

FIGS. 3 to 6 compares Embodiment 2 based on CNT (90%) with a comparative example.

Referring to FIG. 3(a), as a result of analyzing the J-V characteristics in each dark state, the CNT-based photodetector exhibited a dark current of 9.62×10⁻¹³ A/cm² at −1 V bias, which is about 100,000 times or more suppressed as compared to ITO (7.95×10⁻⁸ A/cm²) and PEDOT:PSS (2.91×10⁻⁷ A/cm²).

Referring to FIG. 3(b), it may be appreciated that the CNT-based photodetector of the present disclosure has a high detection rate at a high bias of −1 V as compared to the case of the comparative example.

Referring to FIG. 3(c), it may be appreciated that an LDR value of the CNT-based photodetector of the present disclosure is higher than that of the comparative example.

Referring to FIG. 3(d), it may be appreciated that the CNT-based photodetector of the present disclosure has a lower trap density of 1.59×10¹⁵ cm⁻³ as compared to the case of the comparative example.

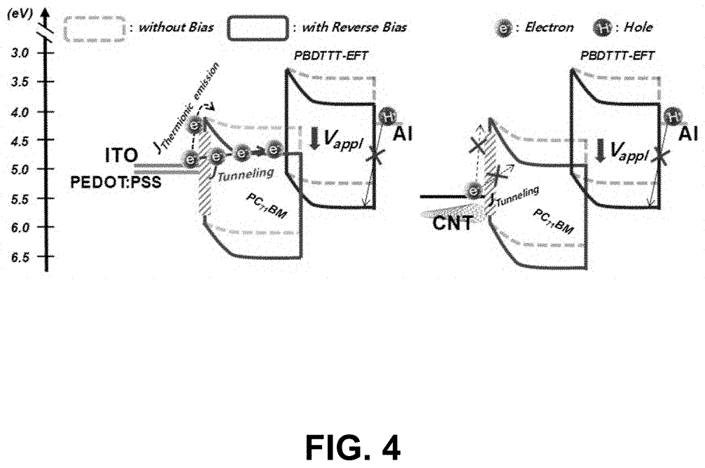

Referring to FIG. 4, it may be appreciated that the CNT-based photodetector of the present disclosure achieves substantially the most effective electron injection barrier with PC71BM which prohibits electron injection by direct tunneling or thermionic emission, and thus exhibits substantially the lowest dark current.

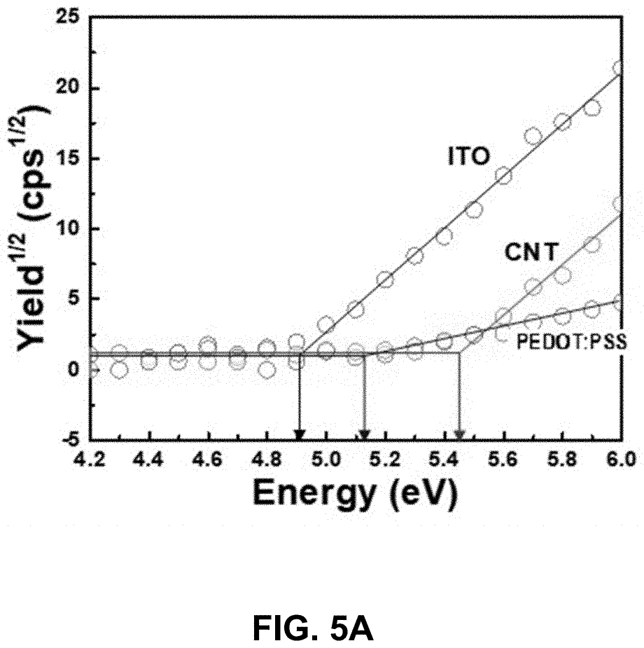

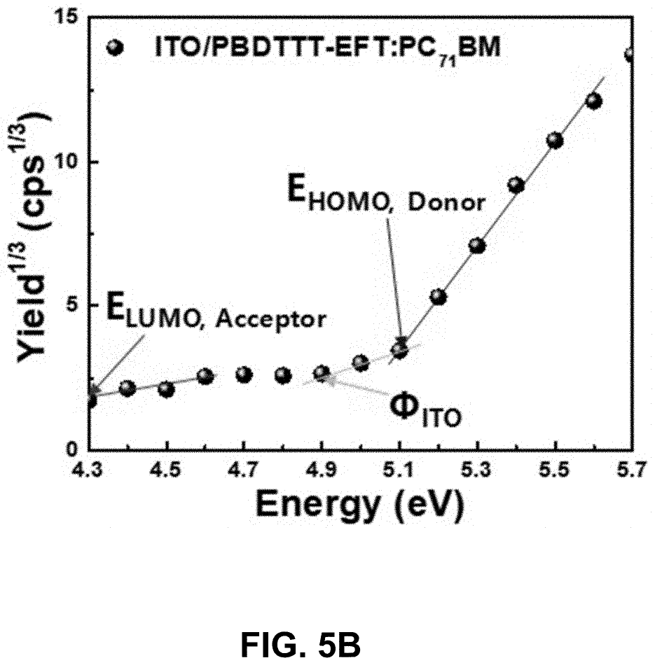

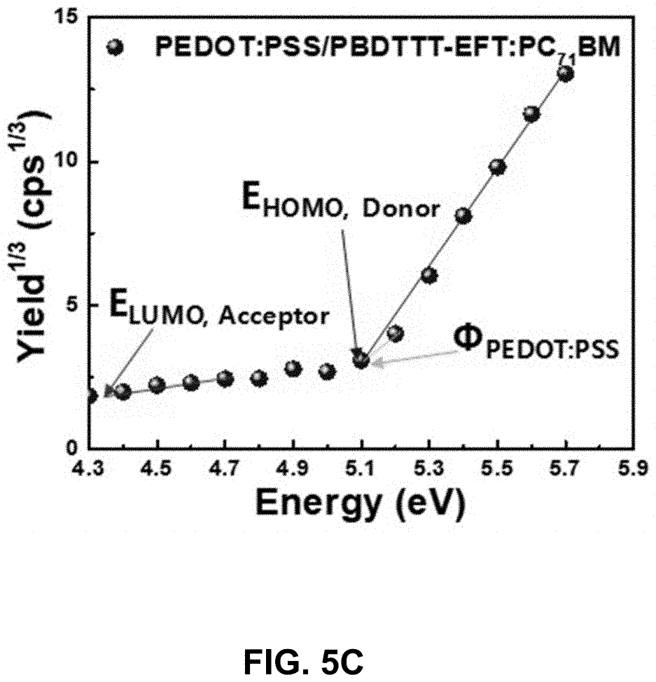

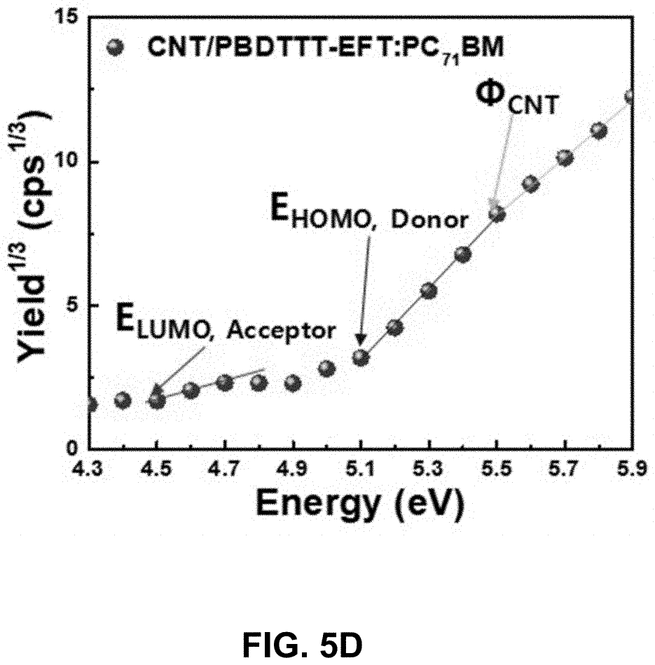

Referring to FIG. 5(a), PYS spectrums of the CNT, ITO and PEDOT:PSS-based electrodes obtained in air were checked. In such a case, work functions of the electrodes were confirmed to be 5.45, 4.91, and 5.12 eV, respectively.

Referring to FIGS. 5(b) to 5(d), the PEDOT:PSS-based electrode had a deep work function, but a higher dark current than that of the ITO-based electrode was observed. In this regard, an energy level of BHJ was investigated at each electrode to explain the energy level banding that has a significant effect on electron injection barriers. Interestingly, through the PYS analysis, it was confirmed that the LUMO energy of PC71BM depends on the work function of the bottom electrode. In the case of the photodetectors to which CNT (90%), ITO and PEDOT:PSS were applied, respectively, it was confirmed that the LUMO values of the PC71BM acceptors were 4.5, 4.35 and 4.3 eV, respectively.

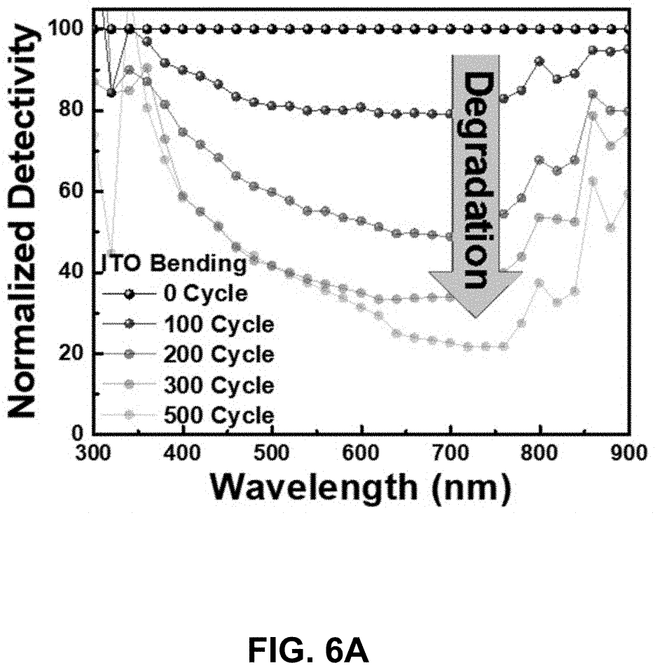

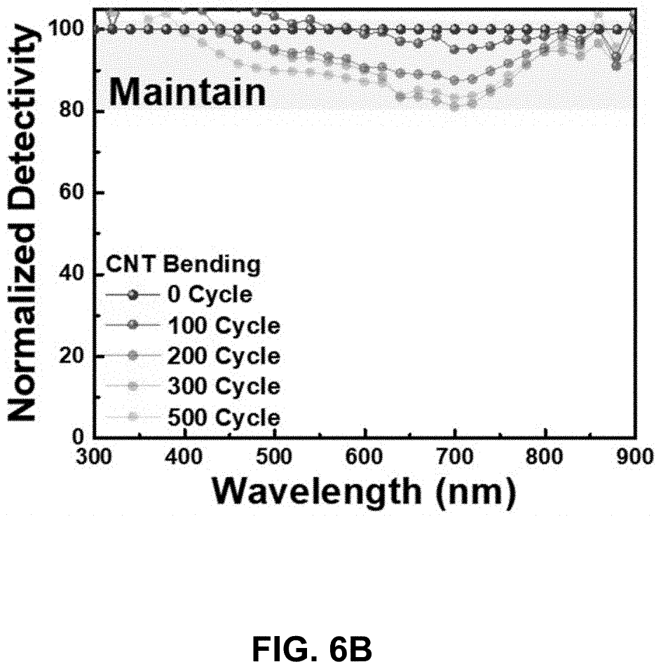

Referring to FIG. 6(a), it was confirmed that performance of the ITO-based photodetector was significantly changed after the 500 bending tests, and the detection rate drops to about 20%. On the other hand, it was confirmed that the CNT-based photodetector maintains 80% of its initial performance even after bending 500 times.

### Experimental Example 2

Table 1 below compares dark currents and detection rates of photodetectors having various structures and photodetectors according to embodiments of the present disclosure.

TABLE 1

| | Dark | | |
|---|---|---|---|
| | current | | |
| | density | Detectivity | |
| Structure | (A/cm²) | (Jones) | Ref. |
| ITO/P3HT:MDMO-PPV:CNTs/ | 1 × 10⁻⁶ | ~5 × 10¹⁰ | [32] |
| SnPc:C₆₀/BCP/Ag | (at 0 V) | (at 0 V) | |
| Graphene/PEDOT:PSS/PEDOT:PSS/ | 4 × 10⁻¹⁰ | 1.3 × 10¹² | [33] |
| P3HT:PC₆₀BM/AI | (at 0 V) | (at 0 V) | |
| CNTs/PEDOT:PSS/P3HT:PC₆₀BM/ | 4 × 10⁻⁷ | — | [34] |
| LiF/AI | (at −5.0 V) | | |
| PEDOT:PSS/PEI/PCDTBT:PC₆₀BM/ | 1.5 × 10⁻¹⁰ | 3.4 × 10¹³ | [35] |
| PEDOT:PSS | (at −5.0 V) | (at −5.0 V) | |
| ITO/PEIE/PCDTBT:PC₆₀BM/ | 3.1 × 10⁻¹⁰ | 3.8 × 10¹³ | [20] |
| PEDOT:PSS | (at −2.0 V) | (at −2.0 V) | |
| CNTs/PEDOT:PSS/ | 1.7 × 10⁻¹³ | 3.2 × 10¹⁴ | This |
| PBDTTT-EFT:PC₇₁BM/PEI/AI | (at −0.5 V) | (at −0.5 V) | work |
| | 9.6 × 10⁻¹³ | 2.1 × 10¹⁴ | |
| | (at −1 V) | (at −1 V) | |

Accordingly, it may be appreciated that the carbon allotrope electrode in which the average transmittance was controlled at a wavelength in a range from 380 to 780 nm not only exhibited excellent mechanical flexibility, but also had effects of suppressing the dark current and improving the detection rate.

As set forth hereinabove, according to one or more embodiments of the present disclosure, a photodetector may successfully realize curved surfaces and flexibility, while being stable to mechanical deformation such as bending and having excellent bending strain.

In addition, according to one or more embodiments of the present disclosure, a photodetector may be improved in terms of photodetection ability by suppressing dark current, as compared to conventional oxide electrode and conductive polymer electrode materials.

What is claimed is:

1. A photodetector comprising:
a carbon allotrope electrode,
wherein the carbon allotrope electrode has an average transmittance in a range from 85% to 95% at a wavelength in a range from 380 nm to 780 nm.

2. The photodetector of claim 1, wherein the photodetector has a flexible structure.

3. The photodetector of claim 1, wherein the carbon allotrope electrode has a trap density adjusted to a range from 1.00×10¹⁰ cm⁻³ to 1.00×10¹⁷ cm⁻³.

4. The photodetector of claim 1, wherein the carbon allotrope electrode has a work function adjusted to a range from 4.80 eV to 5.60 eV.

5. The photodetector of claim 1, wherein the carbon allotrope electrode is p-doped with nitric acid.

6. The photodetector of claim 1, wherein the carbon allotrope electrode is deposited on a polyethylene naphthalate (PEN) substrate.

7. The photodetector of claim 1, further comprising, as a photoreactive layer, a fullerene derivative and PBDTTT-EFT (poly [4,8-bis(5-(2-ethylhexyl)thiophen-2-yl)benzo[1,2-b;4,5-b′]dithiophene-2,6-diyl-alt-(4-(2-ethylhexyl)-3- fluorothieno[3,4-b]thiophene-)-2-carboxylate-2-6-diyl)]).

8. The photodetector of claim 1, further comprising, as an electron blocking layer, PEDOT:PSS (poly(3,4-ethylenediocy-thiophene) doped with poly(styrenesulfonic acid)).

9. The photodetector of claim 1, further comprising polyethyleneimine (PEI) as a hole blocking layer.

10. The photodetector of claim 7, wherein a LUMO energy of a photoreactive layer acceptor formed on the carbon allotrope electrode is adjusted to a range from 4.40 eV to 4.80 eV.

11. A method of preparing the photodetector of claim 1, comprising:
preparing a carbon allotrope film by chemical vapor deposition (CVD);
depositing the carbon allotrope film on a substrate and then p-doping the carbon allotrope film with nitric acid;
applying a bulk heterojunction (BHJ) solution as a photoreactive layer composition on the p-doped film;
applying a charge blocking layer composition on the film applied with the photoreactive layer composition; and
depositing a negative electrode on the film applied with the charge blocking layer composition.
